(19) United States
(12) Patent Application Publication
(10) Pub. No.: US 2013/0062676 A1
(43) Pub. Date: Mar. 14, 2013

(54) FLASH MEMORY STRUCTURE

(71) Applicants: Tzung-Han Lee, Taipei City (TW); Chung-Lin Huang, Taoyuan County (TW); Ron Fu Chu, Taipei City (TW); Dah-Wei Liu, Taipei City (TW)

(72) Inventors: Tzung-Han Lee, Taipei City (TW); Chung-Lin Huang, Taoyuan County (TW); Ron Fu Chu, Taipei City (TW); Dah-Wei Liu, Taipei City (TW)

(21) Appl. No.: 13/239,364

(22) Filed: Sep. 21, 2011

(30) Foreign Application Priority Data
Sep. 14, 2011 (TW) 100133046

(51) Int. Cl. H01L 29/788

(52) U.S. Cl. 257/298; 257/E29.3

(57) ABSTRACT

A flash memory structure includes a semiconductor substrate, a gate dielectric layer on the semiconductor substrate, a floating gate on the gate dielectric layer, a capacitor dielectric layer conformally covering the floating gate, wherein the capacitor dielectric layer forms a top surface and four sidewall surfaces; and an isolated conductive cap layer covering the top surface and the four sidewall surfaces.

### BACKGROUND OF THE INVENTION

1. Field of the Invention

The present invention relates generally to the field of memory technology, and more particularly, to a stacked-gate flash memory structure with improved gate coupling ratio.

2. Description of the Prior Art

As known in the art, flash memories are high-density non-volatile semiconductor memories offering fast access times. The flash memories can store data in the memory under an electrical power off state, and read/write data through controlling a threshold voltage of a control gate.

The flash memory is typically designed as a stacked-gate structure. In a stacked-gate flash memory operation, the stacked-gate electrode comprises a control gate and one or more floating gates separated by a thin dielectric layer, typically ONO (oxide-nitride-oxide) composite dielectric. When the control gate is charged, hot electrons will travel across the gate oxide layer and cause the floating gate to be charged. After the power is turned off, the oxide layer surrounding the floating gate prevents the charge from dissipated. The data stored in the memory is renewed/erased through applying extra energy to the stacked-gate flash memory cell. The control gate to floating gate coupling ratio or the gate coupling ratio (GCR), that is related to the area overlap between control gate and the floating gate, affects the read/write speed of the flash memory.

However, the prior art has some drawbacks. For example, the capacitive coupling between the control gate and the floating gate is insufficient, resulting in poor write/erase efficiency. Therefore, there is a need in this industry to provide an improved flash memory (cell) structure with improved gate coupling ratio.

### SUMMARY OF THE INVENTION

It is one objective of the present invention to provide an improved flash memory (cell) structure with improved gate coupling ratio.

According to one aspect of this invention, a flash memory structure includes a semiconductor substrate; a gate dielectric layer on the semiconductor substrate; a floating gate on the gate dielectric layer; a capacitor dielectric layer conformally covering the floating gate and has a stop surface and four vertical sidewall surfaces; and an isolated conductive cap layer covering the stop surface and four vertical sidewall surfaces of the capacitor dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a partial plan view of an exemplary layout of a flash memory array according to one embodiment of this invention;

FIG. 2A is a schematic, cross-sectional view taken along line AA′ of FIG. 1; and

FIG. 2B is a schematic, cross-sectional view taken along line BB′ of FIG. 1.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

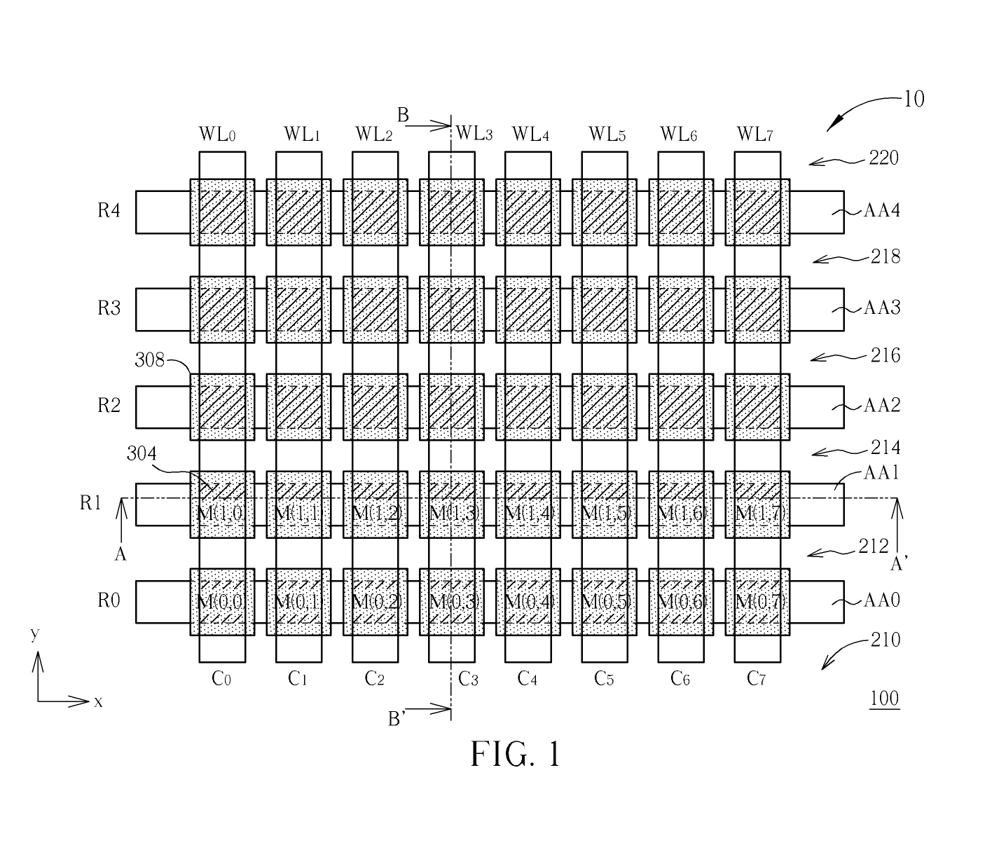

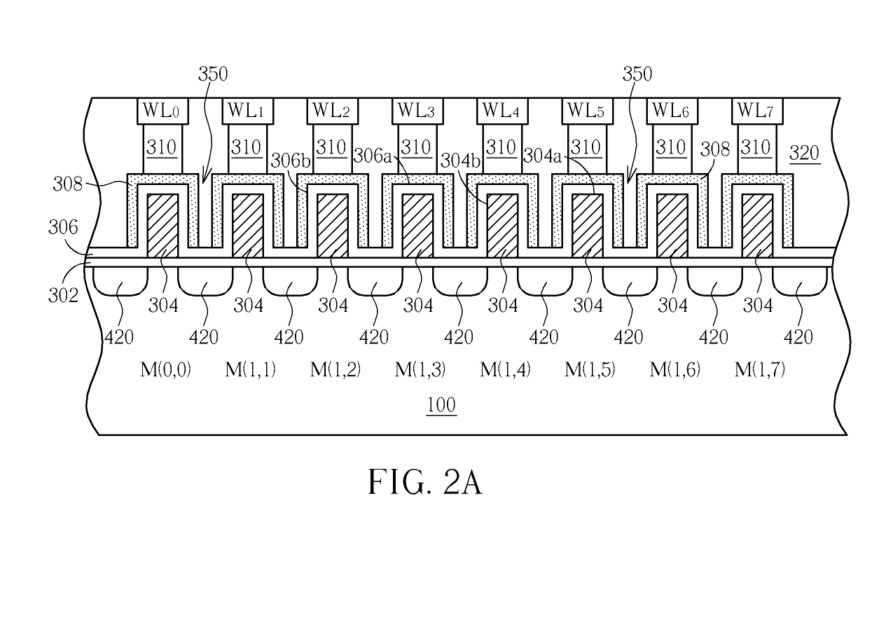

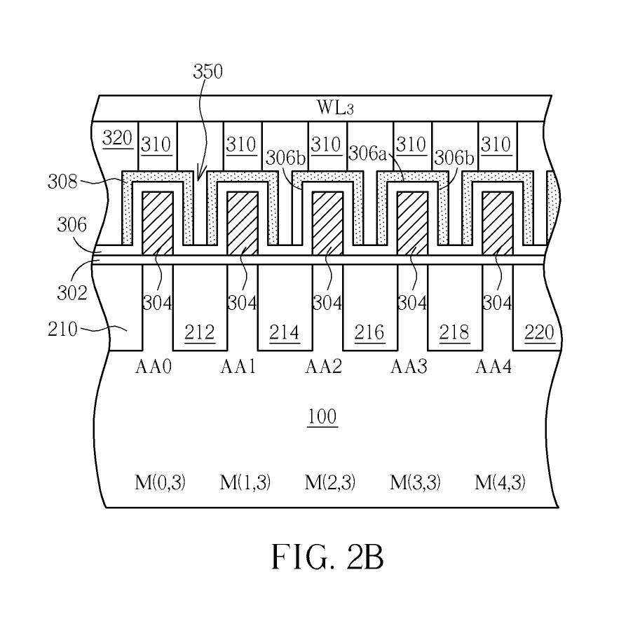

Please refer to FIG. 1, FIG. 2A and FIG. 2B. FIG. 1 is a partial plan view of an exemplary layout of a flash memory array according to one embodiment of this invention. FIG. 2A is a schematic, cross-sectional view taken along line AA′ of FIG. 1. FIG. 2B is a schematic, cross-sectional view taken along line BB′ of FIG. 1. As shown in FIG. 1, the flash memory 10 comprises an array of memory cells, which is denoted M(m, n), wherein m stands for an integral number inclusive or not inclusive of 0 and represents a column number (or raw number) of the memory array, and n stands for an integral number inclusive or not inclusive of 0 and represents a raw number (or column number) of the memory array.

In FIG. 1, for the sake of simplicity, only a 5×8 memory array is demonstrated. That is, the aforesaid memory cells are arranged in a 5-row×8-column matrix, wherein the five rows are denoted as R0˜R4, and the eight columns are denoted as C0˜C7. For example, the memory cells in the first row R0 are denoted as M(0,0)˜M(0,7), and the memory cells in the second row R1 are denoted as M(1,0)˜M(1,7), and so on. The memory cells M(0,0)˜M(0,7) in the first row R0 are fabricated on an active area AA0, the memory cells M(1,0)˜M(1,7) in the second row R1 are fabricated on an active area AA1, and so on. Shallow trench isolation (STI) regions 210˜220 are provided between the active areas AA0˜AA4 to electrically isolate one active area from another. According to the embodiment, the memory cells on the same row of the array are series connected to thereby constitute an NAND memory string. Optionally, a selection transistor (not shown) may be provided at either end of each of the memory strings for switch control.

As shown in FIGS. 2A and 2B, each memory cell has an isolated floating gate 304. More specifically, each of the floating gates 304 has a top surface 304a and four vertical sidewall surfaces 304b. According to the embodiment, each of the floating gates 304 may be analogous to a three-dimensional cubic object or a pillar shaped structure. The floating gates 304 on the same row or on the same column do not physically contact with one another. According to the embodiment, the floating gates 304 may be composed of polysilicon or any suitable conductive materials. Between each of the floating gates 304 and the semiconductor substrate 100, there is provided a gate dielectric layer 302, for example, silicon oxide layer. A capacitor dielectric layer 306, for example, ONO dielectric layer, conformally covers the top surface 304a and the four vertical sidewall surfaces 304b of each of the floating gates 304. According to the embodiment, the capacitor dielectric layer 306 is deposited in a blanket fashion and may cover the bottom surface between the floating gates 304. The capacitor dielectric layer 306 forms a recess 350 between the floating gates 304. According to the embodiment, the capacitor dielectric layer 306 may be stacked on the gate dielectric layer 302 and forms the recess 350.

Since the capacitor dielectric layer 306 conformally covers the top surface 304a and the four vertical sidewall surfaces 304b of each of the floating gates 304, the capacitor dielectric layer 306 also provides a similar top surface 306a and four vertical sidewall surfaces 306b. An isolated conductive cap layer 308 is provided to merely cover the top surface 306a and four vertical sidewall surfaces 306b of the capacitor dielectric layer 306. According to the embodiment, the conductive cap layer 308 may be composed of metals, alloys, polysilicon, silicide, or combinations thereof. The conductive cap layers 308 are physically separated from one another either in the same row or in the same column. That is, the conductive cap layer 308 is merely provided at the address of each of the memory cells to cap each of the floating gates 304 and the conductive cap layer 308 is discontinuous structure. According to the embodiment, the isolated or discontinuous conductive cap layer 308 acts as the control gate of each of the memory cells.

A dielectric layer 320 is deposited over the conductive cap layer 308 and the semiconductor substrate 100. The dielectric layer may fill the recess 350 between the floating gates 304. As seen in FIG. 2A, after planarization, conductive contact plugs 310 and word lines WL0˜WL7 are formed and embedded in the dielectric layer 320. The word lines WL0˜WL7 are electrically coupled to the underlying conductive cap layer 308 of the memory cells M(1,0)˜M(1,7) through respective conductive contact plugs 310. Referring briefly back to FIG. 1, the word lines WL0˜WL7 extend along the reference y-axis. Therefore, taking R1 as an example, the switch (turn-on or turn-off) of the channel of each of the memory cells M(1,0)˜M(1,7) on the same row is controlled by the word lines WL0˜WL7. As previously mentioned, the memory cells on each row of the array are series connected to form an NAND memory string. In FIG. 2A, source/drain doping regions 420 are provided in the semiconductor substrate 100 to form the series connection configuration of the memory cells M(1,0)˜M(1,7). As can be seen in FIG. 2B, each of the word line, taking WL3 as an example, is electrically coupled to the conductive cap layers of corresponding memory cells M(0,3), M(1,3), M(2,3), M(3,3) and M(4,3) on the same column.

To sum up, it is one technical feature of this invention that the floating gate 304 has a top surface 304a and four vertical sidewall surfaces 304b, which are conformally covered by the capacitor dielectric layer 306, to thereby form a similar top surface 306a and four vertical sidewall surfaces 306b. The isolated conductive cap layer 308 acting as a control gate covers the top surface 306a and the four vertical sidewall surfaces 306b. Each of the isolated conductive cap layers 308 is electrically coupled to respective word lines WL0˜WL7 through conductive plugs 310. The memory structure with the isolated conductive cap layer 308 can have improved control gate to floating gate coupling ratio, reduced write/erase voltage and increased write/erase efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory structure, comprising:
a semiconductor substrate;
a gate dielectric layer on the semiconductor substrate;
a floating gate on the gate dielectric layer;
a capacitor dielectric layer conformally covering the floating gate and has a top surface and four sidewall surfaces; and
an isolated conductive cap layer covering the top surface and the four sidewall surfaces of the capacitor dielectric layer.

2. The flash memory structure according to claim 1 wherein the isolated conductive cap layer merely covers the top surface and the four sidewall surfaces of the capacitor dielectric layer.

3. The flash memory structure according to claim 1 wherein the isolated conductive cap layer is discontinuous.

4. The flash memory structure according to claim 1 wherein the isolated conductive cap layer is a control gate.

5. The flash memory structure according to claim 1 further comprising:
a dielectric layer covering the isolated conductive cap layer;
a conductive plug in the dielectric layer to electrically coupled with the isolated conductive cap layer; and
a word line electrically coupled with the conductive plug.

6. The flash memory structure according to claim 1 wherein the isolated conductive cap layer is composed of metals, alloys, polysilicon, silicide, or combinations thereof

7. The flash memory structure according to claim 1 wherein the floating gate is composed of polysilicon.
